(19) United States
(12) Patent Application Publication
(10) Pub. No.: US 2026/0280444 A1
(43) Pub. Date: Sep. 17, 2026

(54) POWER MODULE AND POWER CONVERSION APPARATUS

(71) Applicant: Mitsubishi Electric Corporation, Tokyo (JP)

(72) Inventors: Masaaki ISHINO, Tokyo (JP); Toshiya TADAKUMA, Tokyo (JP); Hodaka ROKUBUICHI, Tokyo (JP); Yuki MATSUTAKA, Tokyo (JP); Kazuki TAKAKURA, Tokyo (JP)

(73) Assignee: Mitsubishi Electric Corporation, Tokyo (JP)

(21) Appl. No.: 19/539,715

(22) Filed: Feb. 13, 2026

(30) Foreign Application Priority Data
Mar. 17, 2025 (JP) 2025-042258

(51) Int. Cl. H02M 7/00; H10W 90/00

(52) U.S. Cl. CPC H02M 7/003; H10W 90/00; H10W 90/724; H10W 90/753; H10W 90/756

(57) ABSTRACT

A power module includes semiconductor groups including a first semiconductor chip and a second semiconductor chip in a package. Each of the semiconductor groups includes a first frame, a second frame, and a third frame. A first electrode of the first semiconductor chip is connected to the first frame, a second electrode of the first semiconductor chip and a first electrode of the second semiconductor chip are connected to the third frame, and a second electrode of the second semiconductor chip is connected to the second frame. Portions of the first frame, the second frame, and the third frame protruding from the package constitute a first terminal, a second terminal, and a third terminal. In the first semiconductor group, at least one of the first semiconductor chip and the second semiconductor chip is different from that of the second semiconductor group.

### BACKGROUND

### Technical Field

The present disclosure relates to a power module and a power conversion apparatus.

### Description of the Background Art

The power conversion apparatus includes various circuits having different functions, such as a PFC circuit, a DC/DC converter circuit, or an inverter circuit. When these circuits are configured by discrete power devices, there is a problem that it is difficult to miniaturize the power conversion apparatus because the occupied area of the semiconductor element increases. Therefore, WO 2017/175686 discloses a power module in which a plurality of power devices are integrated into one package.

In the power module described in WO 2017/175686, a conductor having a pole-mounted structure is arranged in a direction perpendicular to an insulating substrate, and main electrodes are connected to the conductor, so that the main electrodes are arranged in parallel on the substrate, and downsizing of the power module is realized. However, further miniaturization of the power module is desired.

### SUMMARY

An object of the present disclosure is to downsize a power module.

A power module of the present disclosure includes a plurality of semiconductor groups each including a plurality of semiconductor chips in one package. Each of the plurality of semiconductor groups includes a first frame, a second frame, a third frame, a first semiconductor chip, and a second semiconductor chip. A first electrode of the first semiconductor chip is connected to the first frame. A second electrode of the first semiconductor chip and a first electrode of the second semiconductor chip are connected to the third frame. A second electrode of the second semiconductor chip is connected to the second frame. A portion of the first frame protruding from the package constitutes a first terminal. A portion of the second frame protruding from the package constitutes a second terminal. A portion of the third frame protruding from the package constitutes a third terminal. In a first semiconductor group that is at least one semiconductor group among the plurality of semiconductor groups, at least one of the first semiconductor chip and the second semiconductor chip is different from that of a second semiconductor group that is at least one semiconductor group different from the first semiconductor group among the plurality of semiconductor groups.

The power module of the present disclosure includes the first frame, the second frame, and the third frame integrally formed with the first terminal, the second terminal, and the third terminal, so that the parasitic inductance inside the package is reduced. By mounting a plurality of semiconductor groups having different functions in such a low-inductance package, the occupied area of the semiconductor chip is reduced, and downsizing of the power module is realized.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a power module according to a first preferred embodiment;

FIG. 2 is an equivalent circuit diagram of the power module according to the first preferred embodiment;

FIG. 3 is a top view illustrating an arrangement of frames in the power module according to the first preferred embodiment;

FIG. 4 is a diagram illustrating a DC-DC converter using the power module according to the first preferred embodiment;

FIG. 5 is a top view illustrating the power module according to the first preferred embodiment incorporating a snubber capacitor;

FIG. 6 is an equivalent circuit diagram of a power module according to a first modification of the first preferred embodiment;

FIG. 7 is an equivalent circuit diagram of a power module according to a second modification of the first preferred embodiment;

FIG. 8 is an equivalent circuit diagram of a power module according to a third modification of the first preferred embodiment;

FIG. 9 is an equivalent circuit diagram of a power module according to a fourth modification of the first preferred embodiment;

FIG. 10 is an equivalent circuit diagram of a power module according to a fifth modification of the first preferred embodiment;

FIG. 11 is a circuit diagram illustrating details of a usage status of a power module according to the fifth modification of the first preferred embodiment;

FIG. 12 is a top view of the power module according to a second preferred embodiment;

FIG. 13 is a configuration diagram of a power module according to a third preferred embodiment; and

FIG. 14 is a block diagram illustrating a configuration of a power conversion apparatus according to a fourth preferred embodiment.

### DESCRIPTION OF THE PREFERRED EMBODIMENTS

### A. First Preferred Embodiment

### A-1. Configuration

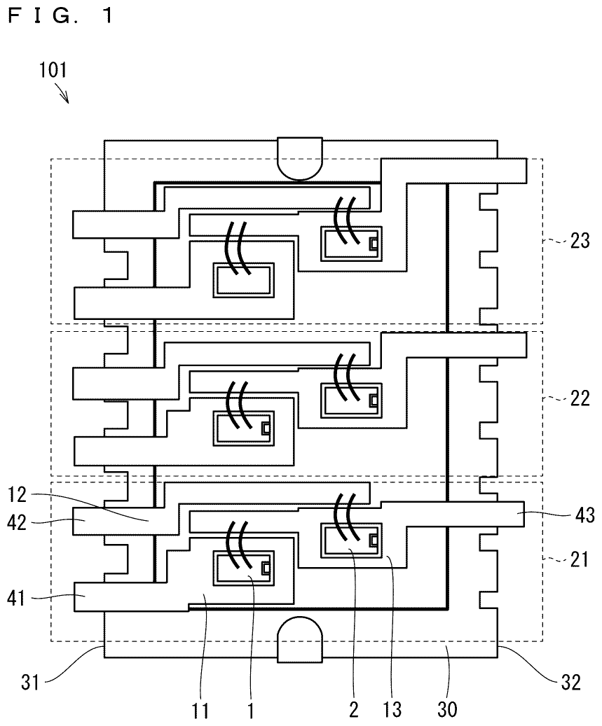

FIG. 1 is a top view of a power module 101 according to a first preferred embodiment.

The power module 101 includes three semiconductor groups 21, 22, and 23 in the package 30. Each of the semiconductor groups 21, 22, and 23 includes a first semiconductor chip 1, a second semiconductor chip 2, a first frame 11, a second frame 12, and a third frame 13.

The first electrode of the first semiconductor chip 1 is connected to the first frame 11. The second electrode of the first semiconductor chip 1 and the first electrode of the second semiconductor chip 2 are connected to the third frame 13. The second electrode of the second semiconductor chip 2 is connected to the second frame 12. The first electrode is a drain when the semiconductor chip is a MOSFET, and is a collector when the semiconductor chip is an IGBT. The second electrode is a source when the semiconductor chip is a MOSFET, and is an emitter when the semiconductor chip is an IGBT.

Two sets of sides facing each other of the package 30 are referred to as a first side 31 and a second side 32, respectively. The first frame 11 and the second frame 12 alternately protrude from the first side 31 of the package 30. When tracing the first side 31 from the bottom to the top in FIG. 1, the first frames 11 and the second frames 12 are alternately arranged such as the first frame 11 and the second frame 12 of the semiconductor group 21, the first frame 11 and the second frame 12 of the semiconductor group 22, and the first frame 11 and the second frame 12 of the semiconductor group 23. The third frame 13 protrudes from the second side 32 of the package 30. A protruding portion of the first frame 11 from the first side 31 constitutes a first terminal 41. A protruding portion of the second frame 12 from the first side 31 constitutes a second terminal 42. A protruding portion of the third frame 13 from the second side 32 constitutes a third terminal 43.

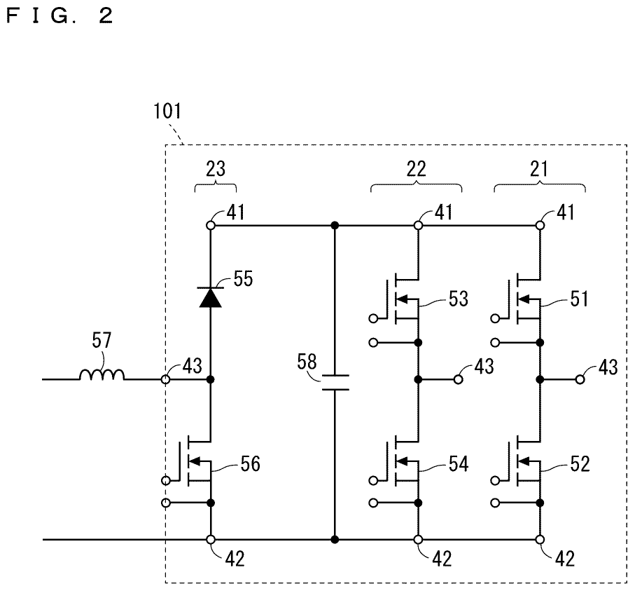

FIG. 2 is an equivalent circuit diagram of the power module 101. According to this equivalent circuit diagram, the power module 101 has a configuration in which the semiconductor groups 21, 22, and 23 are connected in parallel. The semiconductor group 21 includes MOSFETs 51 and 52, the semiconductor group 22 includes MOSFETs 53 and 54, and the semiconductor group 23 includes a diode 55 and a MOSFET 56. The MOSFETs 51 and 52 correspond to the first semiconductor chip 1 and the second semiconductor chip 2 of the semiconductor group 21, respectively. The MOSFETs 53 and 54 correspond to the first semiconductor chip 1 and the second semiconductor chip 2 of the semiconductor group 22, respectively. The diode 55 and the MOSFET 56 correspond to the first semiconductor chip 1 and the second semiconductor chip 2 of the semiconductor group 23, respectively.

The drains of the MOSFETs 51 and 53 and a cathode of the diode 55 are connected to the first terminal 41. Sources of the MOSFETs 52, 54, and 56 are connected to the second terminal 42. Sources of the MOSFETs 51 and 53, drains of the MOSFETs 52, 54, and 56, and an anode of the diode 55 are connected to the third terminal 43. A capacitor 58 outside the power module 101 is connected between the first terminal 41 and the second terminal 42. An inductor 57 outside the power module 101 is connected to the third terminal 43 of the semiconductor group 23.

In the power module 101, the semiconductor groups 21 and 22 are referred to as a first semiconductor group, and the semiconductor group 23 is referred to as a second semiconductor group. At least one of the first semiconductor chip 1 and the second semiconductor chip 2 in the first semiconductor group is different from that in the second semiconductor group. Actually, in the power module 101, the first semiconductor chips 1 of the semiconductor groups 21 and 22 are the MOSFETs 51 and 53, which are different from the diode 55 which is the first semiconductor chip 1 of the semiconductor group 23.

Here, the two semiconductor chips are “different” means that the electrical characteristics of the two semiconductor chips are different. Thus, different types, such as MOSFETs and diodes, are “different” semiconductor chips. Also, different types of switching elements, such as MOSFETs, IGBTs, and BJTs, are “different” semiconductor chips. In addition, semiconductor chips made of different materials, such as the Si-IGBT and the SiC-IGBT, are “different” semiconductor chips. Further, semiconductor chips having different withstand voltages, package shapes, or terminal arrangements are “different” semiconductor chips. Conversely, two semiconductor chips being “identical” means that the electrical characteristics of the two semiconductor chips are identical.

In the example of FIG. 2, the two semiconductor groups 21 and 22 are the first semiconductor group. However, the first semiconductor group may be one semiconductor group, and may be at least one semiconductor group.

### A-2. Action

In the power module 101, since each of the semiconductor groups 21, 22, and 23 has the first terminal 41, the second terminal 42, and the third terminal 43, and the first terminal 41, the second terminal 42, and the third terminal 43 are configured integrally with the first frame 11, the second frame 12, and the third frame 13, respectively, the parasitic inductance inside the package 30 is reduced. As the parasitic inductance decreases, a surge voltage generated by a product of the parasitic inductance and the current change rate during semiconductor switching is suppressed. As a result, the tolerance of the surge voltage with respect to the rated voltage of the power module 101 increases, and a higher current change rate can be allowed, so that high-speed switching can be performed, the switching loss can be reduced by high-speed switching, and the carrier frequency can be increased.

In each of the semiconductor groups 21 and 22 as the first semiconductor group, the first semiconductor chip 1 and the second semiconductor chip 2 are the same MOSFET. Here, the MOSFET is an example of a switching element, and other switching elements such as an IGBT may be used. The semiconductor groups 21 and 22 in which the first semiconductor chip 1 and the second semiconductor chip 2 are configured by the same switching element can be used for an isolated DC/DC converter circuit, an inverter circuit, or the like.

On the other hand, in the semiconductor group 23 which is the second semiconductor group, the first semiconductor chip 1 is the diode 55, and the second semiconductor chip 2 is the MOSFET 56. Here, the MOSFET is an example of a switching element, and other switching elements such as an IGBT may be used. That is, the first semiconductor chip 1 and the second semiconductor chip 2 are different semiconductor chips. Such a semiconductor group 23 can be used for a PFC circuit, a non-isolated DC/DC converter circuit, or the like.

In the power module 101, by mounting both the PFC circuit and the DC/DC converter in the low-inductance package 30, it is possible to realize operation at a high carrier frequency and to reduce the occupied area of the semiconductor chip.

### A-3. Terminal Arrangement

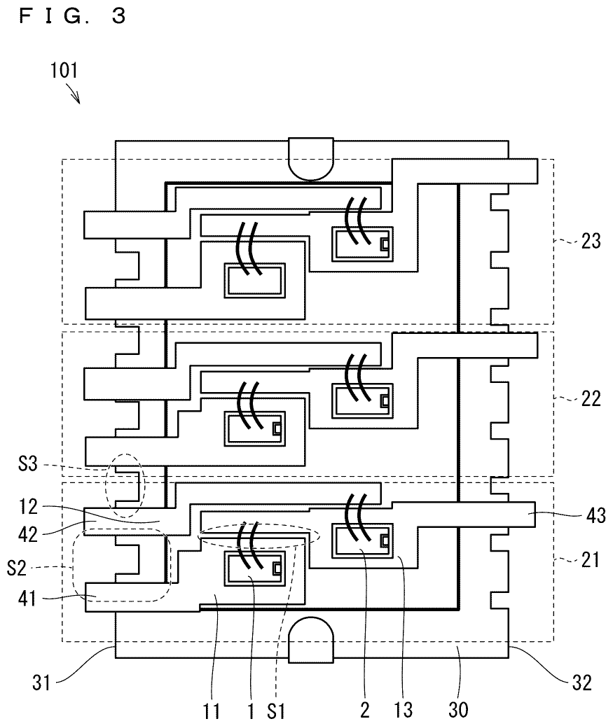

FIG. 3 illustrates an opposing portion of the frame in the power module 101. As illustrated in a broken-line frame S1 in FIG. 3, in each of the semiconductor groups 21, 22, and 23, the second frame 12 and the third frame 13 may have facing portions arranged in parallel with the direction in which the current flows. As a result, since the currents flowing from the upper arm collector terminal to the lower arm emitter terminal flow through the opposing paths, the magnetic fluxes generated by the currents cancel each other. As a result, the parasitic inductance between the second frame 12 and the third frame 13 is reduced.

In addition, as illustrated in a broken-line frame S2 in FIG. 3, in each of the semiconductor groups 21, 22, and 23, the first frame 11 and the second frame 12 may have facing portions arranged in parallel with the direction in which the current flows. As a result, the magnetic flux generated by the current flowing through the first frame 11 and the magnetic flux generated by the current flowing through the second frame 12 cancel each other, and the parasitic inductance between the first frame 11 and the second frame 12 can be reduced.

In addition, as illustrated in a broken-line frame S3 in FIG. 3, in the two adjacent semiconductor groups 21 and 22, the first frame 11 of one semiconductor group 22 and the second frame of the other semiconductor group 21 adjacent thereto may have facing portions arranged in parallel with the current flowing direction. As a result, between the adjacent semiconductor groups, the magnetic flux generated by the current flowing through one first frame 11 and the magnetic flux generated by the current flowing through the other second frame 12 cancel each other, and the parasitic inductance between these frames can be reduced.

In one of the plurality of semiconductor groups 21, 22, and 23 included in the power module 101, the third terminal 43 may protrude from an end on any side of the package 30. In the example of FIG. 3, the third terminal 43 of the semiconductor group 23 protrudes from an end of the second side 32 of the package 30. As a result, the third terminal 43 protruding from the end can be connected to the inductor at the shortest distance.

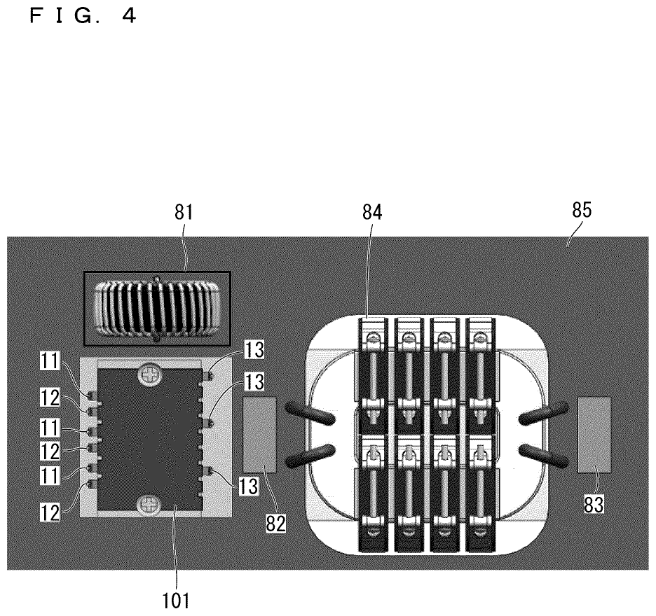

FIG. 4 illustrates an example of a DC-DC converter using the power module 101. The DC-DC converter includes a power module 101, an inductor 81, capacitors 82 and 83, an isolation transformer 84, and a printed circuit board (PCB) 85. By providing the third terminal 43 at the end of the package 30, the connection distance between the third terminal 43 and the inductor 81 can be shortened. This makes it possible to downsize an apparatus using the power module 101, for example, a DC-DC converter.

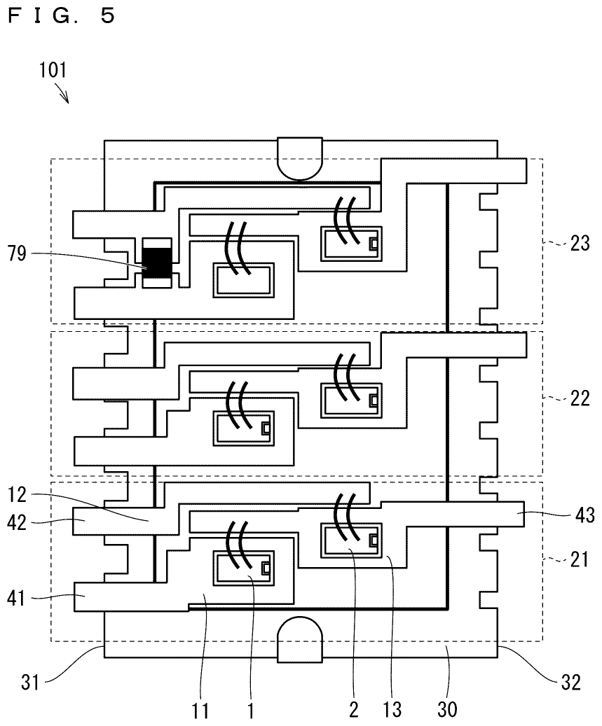

Each of the semiconductor groups 21, 22, and 23 of the power module 101 has no other terminal between the first terminal 41 and the second terminal 42. As a result, as illustrated in FIG. 5, in the power module 101, the snubber capacitor 79 can be mounted between the first terminal 41 and the second terminal 42 in the package 30. As a result, when an apparatus using the power module 101 is configured, it is not necessary to mount a snubber capacitor outside the power module 101, and a component area outside the power module 101 can be reduced. In addition, since the power module 101 incorporates the snubber capacitor 79, the surge voltage can be suppressed, and high-speed switching operation and operation at a high carrier frequency can be performed. As a result, it is possible to downsize peripheral components outside the power module 101, such as a heat sink or a reactor.

### A-4. Switching

Each of the semiconductor groups 21, 22, and 23 of the power module 101 is switched by a control circuit outside the power module 101. At least one semiconductor group among the semiconductor groups 21, 22, and 23 may be controlled by hard switching, and the other at least one semiconductor group may be controlled by soft switching.

In the semiconductor group controlled by soft switching, it is desirable that the first semiconductor chip 1 and the second semiconductor chip 2 are all configured by the same switching element. At least one semiconductor group in which the first semiconductor chip 1 and the second semiconductor chip 2 are all configured by the same switching element is used for, for example, a DC/DC converter circuit. In this case, the DC/DC converter circuit can be operated by an optimum control method.

In the DC/DC converter circuit, it is necessary to increase the carrier frequency in order to downsize the isolation transformer connected to the output unit. The soft switching can reduce the switching loss as compared with the hard switching. Therefore, the carrier frequency can be increased by applying the soft switching to the DC/DC converter circuit.

In the semiconductor group controlled by hard switching, a semiconductor group in which at least one of the first semiconductor chip 1 and the second semiconductor chip 2 is a diode is used for, for example, a PFC circuit.

In other words, at least one semiconductor group controlled by hard switching constitutes a PFC circuit, and at least one semiconductor group controlled by soft switching constitutes a DC/DC converter circuit. The PFC circuit does not require a higher carrier frequency than the DC/DC converter circuit. Therefore, the configuration of the control circuit can be simplified by operating the PFC circuit by hard switching.

Although the examples of the DC/DC converter circuit and the PFC circuit have been described above, the carrier frequency of the semiconductor group controlled by hard switching is desirably lower than the carrier frequency of the semiconductor group controlled by soft switching. Since a semiconductor group having a high carrier frequency has a large switching loss, it is desirable to reduce the switching loss by soft switching.

### A-5. First Modification

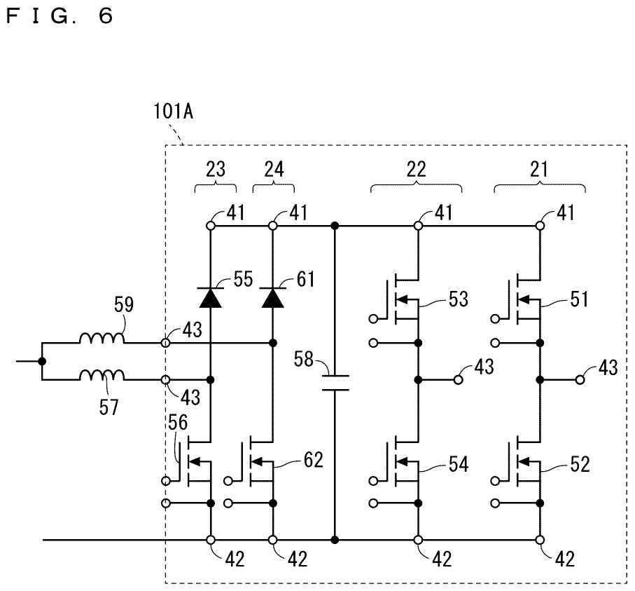

Although the power module 101 illustrated in FIGS. 1 and 2 includes the three semiconductor groups 21, 22, and 23, the number of semiconductor groups included in the power module 101 may be two or four or more. A power module including four semiconductor groups 21, 22, 23, and 24 is defined as a power module 101A according to a first modification, and an equivalent circuit diagram thereof is illustrated in FIG. 6.

In the power module 101A, the first semiconductor chip 1 of the semiconductor group 24 is a diode 61, and the second semiconductor chip 2 is a MOSFET 62. A cathode of the diode 61 is connected to the first terminal 41, a source of the MOSFET 62 is connected to the second terminal 42, and an anode of the diode 61 and a drain of the MOSFET 62 are connected to the third terminal 43. An inductor 59 outside the power module 101A is connected to the third terminal 43 of the semiconductor group 24. Other configurations of the power module 101A are similar to those of the power module 101.

In the power module 101A, the semiconductor groups 21 and 22 correspond to the first semiconductor group, and the semiconductor groups 23 and 24 correspond to the second semiconductor group. According to the power module 101A, since the carrier frequency of the second semiconductor group is half the circuit frequency, the switching loss can be reduced.

### A-6. Second Modification

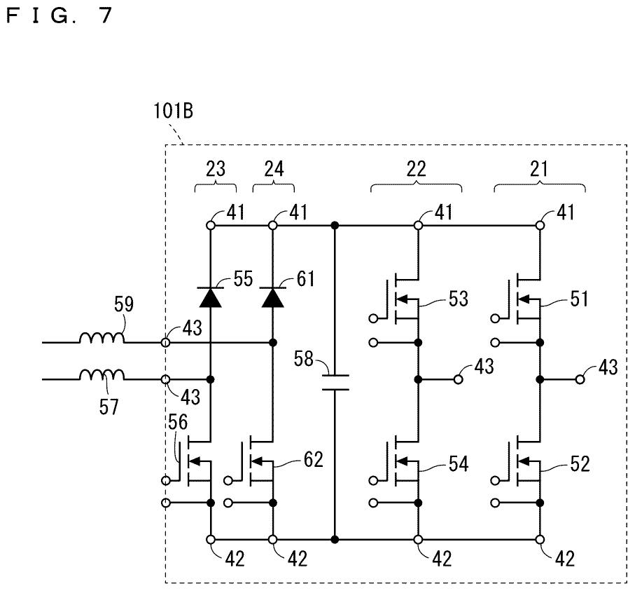

As compared with the power module 101A, a power module in which the inductors 57 and 59 connected to the semiconductor groups 23 and 24 outside the power module are not directly connected to each other and the third terminal 42 connected to the sources of the semiconductor groups 23 and 24 is not connected to an external circuit is defined as a power module 101B according to a second modification, and an equivalent circuit diagram thereof is illustrated in FIG. 7.

According to the power module 101B, the diode bridge becomes unnecessary on the primary side of the semiconductor groups 23 and 24, and the loss can be reduced.

### A-7. Third Modification

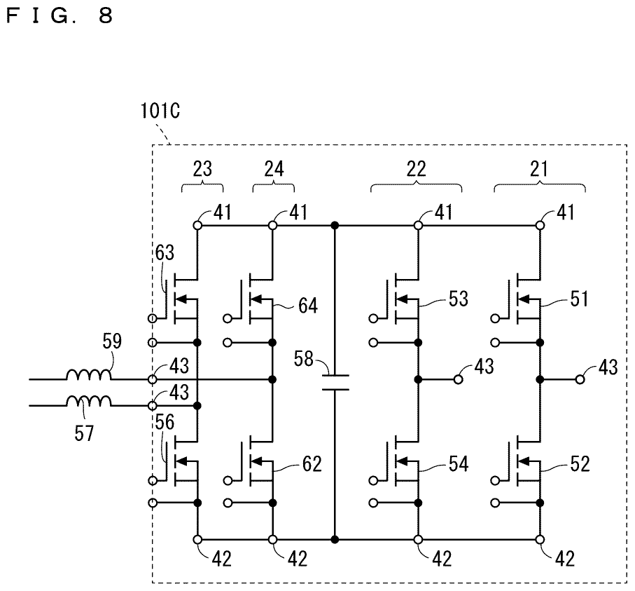

In the semiconductor groups 23 and 24 of the power module 101A, a power module obtained by replacing all first semiconductor chips 1 from the diodes 55 and 61 to the MOSFETs 63 and 64 is defined as a power module 101C according to a third modification, and an equivalent circuit diagram thereof is illustrated in FIG. 8.

In the semiconductor groups 21, 22, 23, and 24 of the power module 101C, both the first semiconductor chip 1 and the second semiconductor chip 2 are MOSFETs. That is, in each of the semiconductor groups 21, 22, 23, and 24, the first semiconductor chip 1 and the second semiconductor chip 2 are the same semiconductor chip and are the same switching element.

However, the MOSFETs 51 and 53 constituting the first semiconductor chips 1 of the semiconductor groups 21 and 22, which are the first semiconductor groups, and the MOSFETs 63 and 64 constituting the first semiconductor chips 1 of the other semiconductor groups 23 and 24 are MOSFETs having different electrical characteristics. Similarly, the MOSFETs 52 and 54 constituting the second semiconductor chips 2 of the semiconductor groups 21 and 22, which are the first semiconductor groups, and the MOSFETs 63 and 64 constituting the first semiconductor chips 1 of the other semiconductor groups 23 and 24 are MOSFETs having different electrical characteristics.

According to the power module 101C, in addition to the loss reduction due to the reduction of the diode bridge, the efficiency is further improved by utilizing the synchronous rectification operation of the MOSFET from the diode conduction.

### A-8. Fourth Modification

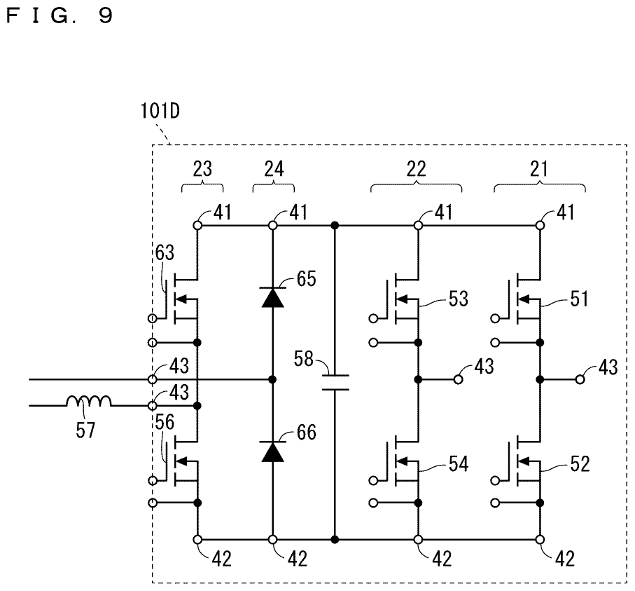

FIG. 9 illustrates an equivalent circuit diagram of a power module 101D according to a fourth modification. The power module 101D is a power module in which the first semiconductor chip 1 and the second semiconductor chip 2 of the semiconductor group 24 in the power module 101C are a diode 65 and a diode 66. In other words, in the power module 101D, the semiconductor groups 23 and 24 which are the second semiconductor groups include the semiconductor group 24 in which both the first semiconductor chip 1 and the second semiconductor chip 2 are diodes.

According to the power module 101D, in addition to the loss reduction due to the functions of the diode bridge and the PFC circuit, the efficiency is further improved by the synchronous rectification operation of the MOSFET.

### A-9. Fifth Modification

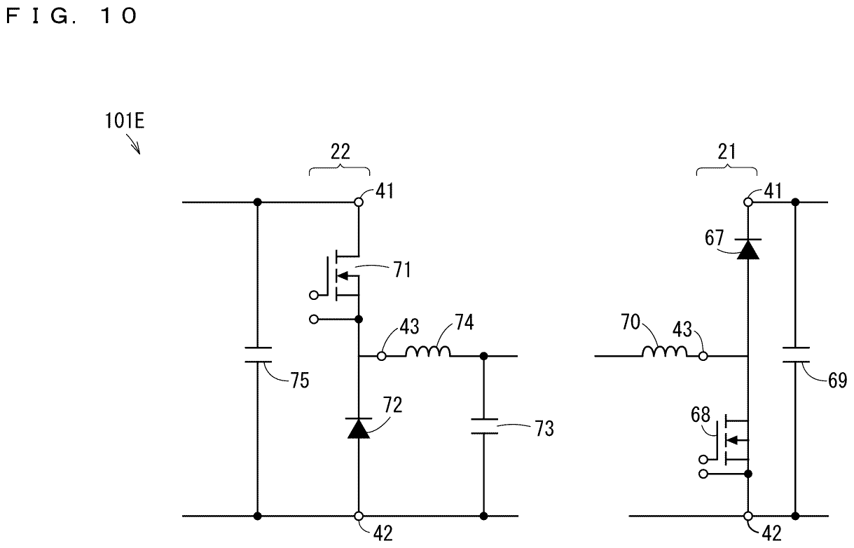

In the power module 101, the first semiconductor chip 1 and the second semiconductor chip 2 in the first semiconductor group were both MOSFETs and semiconductor chips having the same electrical characteristics. However, the first semiconductor chip 1 and the second semiconductor chip 2 in the first semiconductor group may be different semiconductor chips, and as an example, an equivalent circuit diagram of a power module 101E according to a fifth modification is illustrated in FIG. 10.

The power module 101E includes the semiconductor groups 21 and 22. The semiconductor group 21 includes a diode 67 and a MOSFET 68 as the first semiconductor chip 1 and the second semiconductor chip 2. In the power module 101E, the semiconductor group 21 corresponds to the first semiconductor group. In the semiconductor group 21, a capacitor 69 outside the power module 101E is connected between the first terminal 41 and the second terminal 42, and an inductor 70 outside the power module 101E is connected to the third terminal 43.

The semiconductor group 22 includes a MOSFET 71 and a diode 72 as the first semiconductor chip 1 and the second semiconductor chip 2. In the semiconductor group 22, the capacitor 75 outside the power module 101E is connected between the first terminal 41 and the second terminal 42, the capacitor 73 outside the power module 101E is connected between the third terminal 43 and the second terminal 42, and the inductor 74 outside the power module 101E is connected to the third terminal 43.

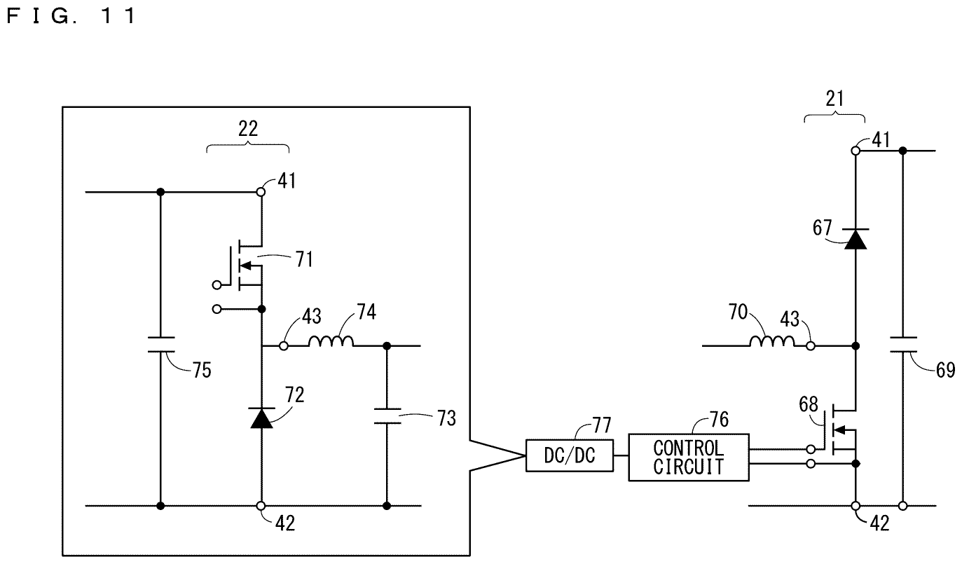

FIG. 11 is a circuit diagram illustrating a situation in which the power module 101E is used in detail. The semiconductor group 21 operates as a boost chopper or a PFC circuit of a main circuit. The semiconductor group 22 is used as a DC/DC converter circuit 77 that supplies a voltage to a control circuit 76 that controls switching of the semiconductor group 21. The specifications of the MOSFET and the diode in the semiconductor group 21 are different from the specifications of the MOSFET and the diode in the semiconductor group 22. The semiconductor group 22 handles less power than the semiconductor group 21.

### B. Second Preferred Embodiment

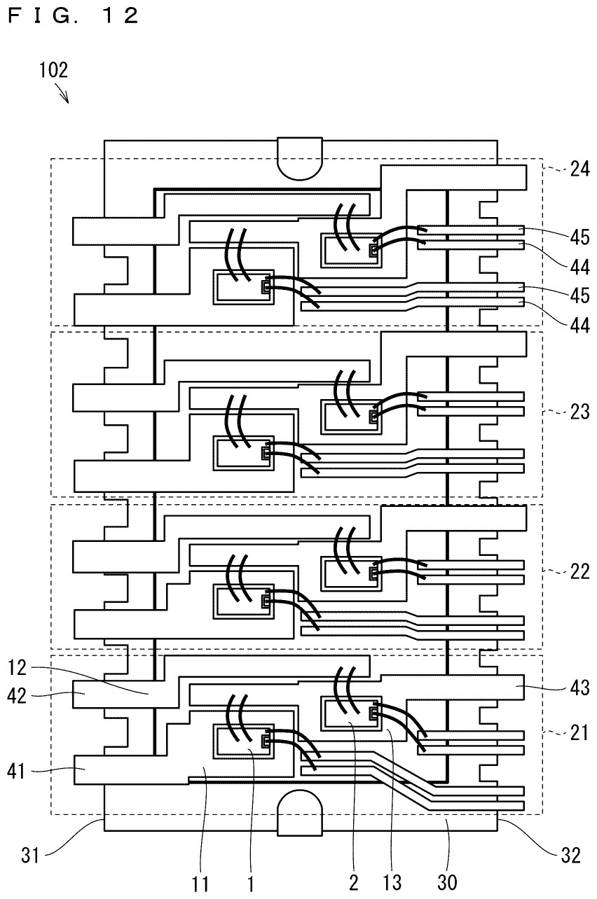

FIG. 12 is a top view of a power module 102 according to a second preferred embodiment.

The power module 102 includes a fourth terminal 44 and a fifth terminal 45 in addition to the configuration of the power module 101A according to the first preferred embodiment. The fourth terminal 44 and the fifth terminal 45 protrude from the second side 32 of the package 30 to the outside of the package 30. The fourth terminal 44 is connected to a gate of a semiconductor chip, which is a switching element, between the first semiconductor chip 1 and the second semiconductor chip 2 and functions as a control terminal. The fifth terminal 45 is connected to the second electrode of the semiconductor chip, which is a switching element, between the first semiconductor chip 1 and the second semiconductor chip 2.

Here, the configuration in which the fourth terminal 44 and the fifth terminal 45 are included in the configuration of the power module 101A has been described, but the configuration in which the fourth terminal 44 and the fifth terminal 45 are included is applicable to the power module according to the first preferred embodiment and any modification thereof.

In the power module 102, since the fourth terminal 44 and the fifth terminal 45 are provided on the second side 32 different from the first side 31 of the package 30 on which the first terminal 41 and the second terminal 42 are provided, the interval between the first terminal 41 and the second terminal 42 can be narrowed. As a result, at the time of energization, the effect of canceling the magnetic flux generated by the current flowing through the first terminal 41 and the magnetic flux generated by the current flowing through the second terminal 42 is enhanced, and the parasitic inductance is reduced. Therefore, it is possible to reduce the surge voltage generated by the current change rate at the time of switching of the semiconductor element and the parasitic inductance inside the package 30.

### C. Third Preferred Embodiment

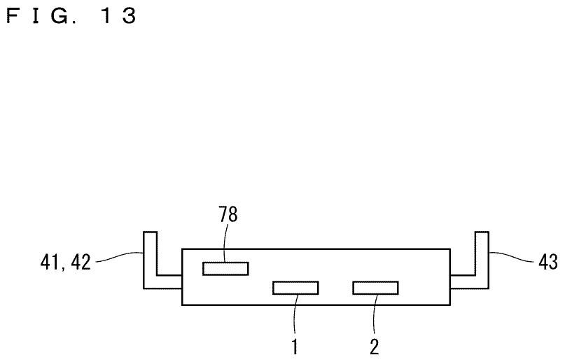

FIG. 13 is a diagram illustrating a configuration of a power module 103 according to a third preferred embodiment. The power module 103 includes a control circuit 78 that controls the first semiconductor chip 1 and the second semiconductor chip 2 in the package 30 in addition to the configuration of the power module 101 according to the first preferred embodiment. In FIG. 13, the frame is not illustrated. The power module 103 has the same configuration as the power module 101 except for the control circuit 78.

Usually, a control circuit is formed on a PCB substrate on which a power module is mounted. However, since the power module 103 incorporates the control circuit 78, it is not necessary to provide a control circuit on the PCB substrate. As a result, the layout on the PCB substrate is facilitated, and the power conversion apparatus using the power module 103 can be downsized.

A method of controlling each semiconductor group by the control circuit 78 is similar to the control method by the control circuit outside the power module 101 described in <A-4. Switching> of the first preferred embodiment.

### D. Fourth Preferred Embodiment

In the present preferred embodiment, the power module according to the first to third preferred embodiments described above is applied to a power conversion apparatus. Although the application of the power module according to the first to third preferred embodiments is not limited to a specific power conversion apparatus, a case where the power module according to the first to third preferred embodiments is applied to a three-phase inverter will be described below as a fourth preferred embodiment.

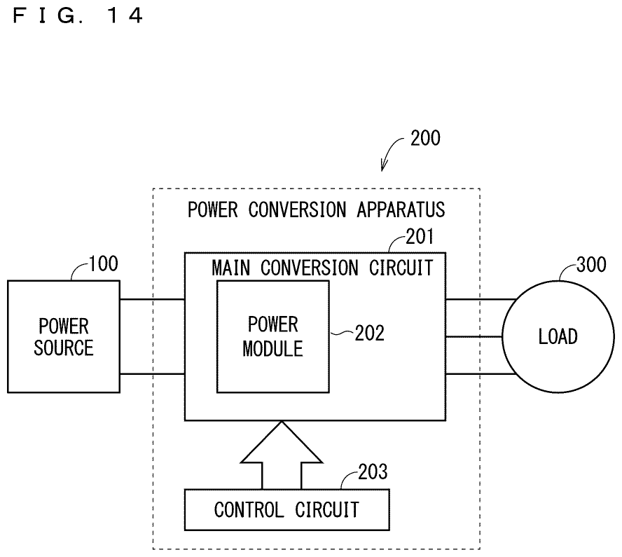

FIG. 14 is a block diagram illustrating a configuration of a power conversion system to which the power conversion apparatus according to the present preferred embodiment is applied.

The power conversion system illustrated in FIG. 14 includes a power supply 100, a power conversion apparatus 200, and a load 300. The power supply 100 is a direct current power supply, and supplies direct current power to the power conversion apparatus 200. The power supply 100 can include various components, and can include, for example, a direct current system, a solar cell, and a storage battery, or may include a rectifier circuit or an AC/DC converter connected to an alternating current system. Further, the power supply 100 may include a DC/DC converter that converts direct current power output from the direct current system into predetermined power.

The power conversion apparatus 200 is a three-phase inverter connected between the power supply 100 and the load 300, converts direct current power supplied from the power supply 100 into alternating current power, and supplies the alternating current power to the load 300. As illustrated in FIG. 14, the power conversion apparatus 200 includes a main conversion circuit 201 that converts direct current power into alternating current power and outputs the alternating current power, and a control circuit 203 that outputs a control signal for controlling the main conversion circuit 201 to the main conversion circuit 201.

The load 300 is a three-phase electric motor driven by the alternating current power supplied from the power conversion apparatus 200. The load 300 is not limited to a specific application, but is an electric motor mounted on various electric devices, and is used as, for example, an electric motor for a hybrid vehicle, an electric vehicle, a railway vehicle, an elevator, or an air conditioner.

Hereinafter, details of the power conversion apparatus 200 will be described. The main conversion circuit 201 includes a switching element and a freewheeling diode (not illustrated), converts direct current power supplied from the power supply 100 into alternating current power by switching of the switching element, and supplies the alternating current power to the load 300. Although there are various specific circuit configurations of the main conversion circuit 201, the main conversion circuit 201 according to the present preferred embodiment is a two-level three-phase full bridge circuit, and can include six switching elements and six freewheeling diodes antiparallel to the respective switching elements. At least one of each switching element and each freewheeling diode of the main conversion circuit 201 is configured by the power module 202 corresponding to the power module of any one of the first to third preferred embodiments described above. The six switching elements are connected in series for every two switching elements to constitute upper and lower arms, and each of the upper and lower arms constitutes each phase (U-phase, V-phase, W-phase) of the full bridge circuit. The output terminals of the upper and lower arms, that is, the three output terminals of the main conversion circuit 201 are connected to the load 300.

Further, the main conversion circuit 201 includes a drive circuit (not illustrated) that drives each switching element, but the drive circuit may be incorporated in the power module 202, or may include a drive circuit separately from the power module 202. The drive circuit generates a drive signal for driving the switching element of the main conversion circuit 201, and supplies the drive signal to the control electrode of the switching element of the main conversion circuit 201. Specifically, in accordance with a control signal from the control circuit 203 to be described later, a drive signal for turning on the switching element and a drive signal for turning off the switching element are output to the control electrode of each switching element. When the switching element is maintained in the ON state, the drive signal is a voltage signal (ON signal) equal to or higher than the threshold voltage of the switching element, and when the switching element is maintained in the OFF state, the drive signal is a voltage signal (OFF signal) equal to or lower than the threshold voltage of the switching element.

The control circuit 203 controls the switching elements of the main conversion circuit 201 so that desired power is supplied to the load 300. Specifically, a time (ON time) during which each switching element of the main conversion circuit 201 is to be turned on is calculated based on the power to be supplied to the load 300. For example, the main conversion circuit 201 can be controlled by PWM control that modulates the ON time of the switching element according to the voltage to be output. Then, a control command (control signal) is output to the drive circuit included in the main conversion circuit 201 such that an ON signal is output to the switching element to be turned on at each time point, and an OFF signal is output to the switching element to be turned off at each time point. The drive circuit outputs an ON signal or an OFF signal as a drive signal to the control electrode of each switching element according to the control signal.

In the power conversion apparatus according to the present preferred embodiment, since the power module according to the first to third preferred embodiments is applied as the switching element and the freewheeling diode of the main conversion circuit 201, downsizing can be realized.

In the present preferred embodiment, the example in which the power module according to the first to third preferred embodiments is applied to the two-level three-phase inverter has been described, but the application of the power module according to the first to third preferred embodiments is not limited thereto, and can be applied to various power conversion apparatuses. In the present preferred embodiment, a two-level power conversion apparatus is used, but a three-level or multi-level power conversion apparatus may be used. In a case where power is supplied to a single-phase load, the power module according to the first to third preferred embodiments may be applied to a single-phase inverter. When power is supplied to a direct current load or the like, the power module according to the first to third preferred embodiments can also be applied to a DC/DC converter or an AC/DC converter.

In addition, the power conversion apparatus to which the power module according to the first to third preferred embodiments is applied is not limited to the case where the load described above is an electric motor, and can also be used as, for example, a power supply apparatus of an electric discharge machine, a laser beam machine, an induction heating cooker, or a noncontact power supply system, and can also be used as a power conditioner of a solar power generation system, a power storage system, or the like.

Although the preferred embodiments and the like have been described in detail above, the present invention is not limited to the above-described preferred embodiments and the like, and various modifications and substitutions can be made to the above-described preferred embodiments and the like without departing from the scope described in the claims.

Hereinafter, various aspects of the present disclosure will be collectively described as appendices.

### Appendix 1

A power module comprising a plurality of semiconductor groups each including a plurality of semiconductor chips in one package,
wherein
each of the plurality of semiconductor groups includes
   a first frame,
   a second frame,
   a third frame,
   a first semiconductor chip, and
   a second semiconductor chip,
a first electrode of the first semiconductor chip is connected to the first frame,
a second electrode of the first semiconductor chip and a first electrode of the second semiconductor chip are connected to the third frame,
a second electrode of the second semiconductor chip is connected to the second frame,
a portion of the first frame protruding from the package constitutes a first terminal,
a portion of the second frame protruding from the package constitutes a second terminal,
a portion of the third frame protruding from the package constitutes a third terminal, and
in a first semiconductor group that is at least one semiconductor group among the plurality of semiconductor groups, at least one of the first semiconductor chip and the second semiconductor chip is different from that of a second semiconductor group that is at least one semiconductor group different from the first semiconductor group among the plurality of semiconductor groups.

### Appendix 2

The power module according to Appendix 1, wherein
in each of the first semiconductor groups, the first semiconductor chip and the second semiconductor chip are the same semiconductor chip.

### Appendix 3

The power module according to Appendix 1 or 2, wherein
in each of the second semiconductor groups, the first semiconductor chip and the second semiconductor chip are different semiconductor chips.

### Appendix 4

The power module according to Appendix 3, wherein
in each of the second semiconductor groups, the first semiconductor chip is a diode, and the second semiconductor chip is a switching element.

### Appendix 5

The power module according to Appendix 1, wherein
in each of the plurality of semiconductor groups, the first semiconductor chip and the second semiconductor chip are the same semiconductor chip.

### Appendix 6

The power module according to Appendix 5, wherein
the second semiconductor group includes a semiconductor group in which both the first semiconductor chip and the second semiconductor chip are diodes.

### Appendix 7

The power module according to Appendix 5, wherein
in each of the plurality of semiconductor groups, the first semiconductor chip and the second semiconductor chip are the same switching element.

### Appendix 8

The power module according to any one of Appendices 1 to 7, wherein
the first terminal and the second terminal of the plurality of semiconductor groups alternately protrude from a first side of the package, and the third terminal protrudes from a second side different from the first side of the package.

### Appendix 9

The power module according to Appendix 8, wherein
the plurality of semiconductor groups includes a semiconductor group in which at least one of the first semiconductor chip and the second semiconductor chip is a switching element, and
the power module includes
a fourth terminal connected to a gate of the switching element and protruding from the second side of the package, and
a fifth terminal connected to the second electrode of the switching element and protruding from the second side of the package.

### Appendix 10

The power module according to any one of Appendices 1 to 9, wherein
in each of the plurality of semiconductor groups, the second frame and the third frame have facing portions arranged in parallel with each other.

### Appendix 11

The power module according to any one of Appendices 1 to 10, wherein
in each of the plurality of semiconductor groups, the first frame and the second frame have facing portions arranged in parallel with each other.

### Appendix 12

The power module according to any one of Appendices 1 to 11, wherein
in two adjacent semiconductor groups among the plurality of semiconductor groups, the first frame of one semiconductor group and the second frame of the other semiconductor group have facing portions arranged in parallel with each other.

### Appendix 13

The power module according to any one of Appendices 1 to 12, wherein
in one semiconductor group among the plurality of semiconductor groups, the third terminal protrudes from an end on any side of the package.

### Appendix 14

The power module according to any one of Appendices 1 to 13, wherein
at least one semiconductor group among the plurality of semiconductor groups has no other terminal between the first terminal and the second terminal.

### Appendix 15

The power module according to any one of Appendices 1 to 14, wherein
at least one semiconductor group among the plurality of semiconductor groups is controlled by hard switching, and at least another semiconductor group is controlled by soft switching.

### Appendix 16

The power module according to Appendix 15, wherein
in at least one semiconductor group of the at least one semiconductor group controlled by hard switching, at least one of the first semiconductor chip and the second semiconductor chip is a diode.

### Appendix 17

The power module according to Appendix 15 or 16, wherein
in the at least one semiconductor group controlled by soft switching, the first semiconductor chip and the second semiconductor chip are the same switching element.

### Appendix 18

The power module according to any one of Appendices 15 to 17, wherein
the at least one semiconductor group controlled by hard switching constitutes a PFC circuit, and
the at least one semiconductor group controlled by soft switching constitutes a DC/DC converter.

### Appendix 19

The power module according to any one of Appendices 15 to 18, wherein
a carrier frequency of the at least one semiconductor group controlled by hard switching is lower than a carrier frequency of the at least one semiconductor group controlled by soft switching.

### Appendix 20

The power module according to any one of Appendices 1 to 19, further comprising
a control circuit provided in the package that controls the first semiconductor chip and the second semiconductor chip.

### Appendix 21

A power conversion apparatus comprising:
a main conversion circuit that includes the power module according to any one of Appendices 1 to 19 and converts and outputs input power; and
a control circuit that outputs a control signal for controlling the main conversion circuit to the main conversion circuit.

While the disclosure has been shown and described in detail, the foregoing description is in all aspects illustrative and not restrictive. It is therefore understood that numerous modifications and variations can be devised.

What is claimed is:

1. A power module comprising a plurality of semiconductor groups each including a plurality of semiconductor chips in one package,
wherein
each of the plurality of semiconductor groups includes
a first frame,
a second frame,
a third frame,
a first semiconductor chip, and
a second semiconductor chip,
a first electrode of the first semiconductor chip is connected to the first frame,
a second electrode of the first semiconductor chip and a first electrode of the second semiconductor chip are connected to the third frame,
a second electrode of the second semiconductor chip is connected to the second frame,
a portion of the first frame protruding from the package constitutes a first terminal,
a portion of the second frame protruding from the package constitutes a second terminal,
a portion of the third frame protruding from the package constitutes a third terminal, and
in a first semiconductor group that is at least one semiconductor group among the plurality of semiconductor groups, at least one of the first semiconductor chip and the second semiconductor chip is different from that of a second semiconductor group that is at least one semiconductor group different from the first semiconductor group among the plurality of semiconductor groups.

2. The power module according to claim 1, wherein
in each of the first semiconductor groups, the first semiconductor chip and the second semiconductor chip are the same semiconductor chip.

3. The power module according to claim 1, wherein
in each of the second semiconductor groups, the first semiconductor chip and the second semiconductor chip are different semiconductor chips.

4. The power module according to claim 3, wherein
in each of the second semiconductor groups, the first semiconductor chip is a diode, and the second semiconductor chip is a switching element.

5. The power module according to claim 1, wherein
in each of the plurality of semiconductor groups, the first semiconductor chip and the second semiconductor chip are the same semiconductor chip.

6. The power module according to claim 5, wherein
the second semiconductor group includes a semiconductor group in which both the first semiconductor chip and the second semiconductor chip are diodes.

7. The power module according to claim 5, wherein
in each of the plurality of semiconductor groups, the first semiconductor chip and the second semiconductor chip are the same switching element.

8. The power module according to 1, wherein
the first terminal and the second terminal of the plurality of semiconductor groups alternately protrude from a first side of the package, and the third terminal protrudes from a second side different from the first side of the package.

9. The power module according to claim 8, wherein
the plurality of semiconductor groups includes a semiconductor group in which at least one of the first semiconductor chip and the second semiconductor chip is a switching element, and
the power module includes
a fourth terminal connected to a gate of the switching element and protruding from the second side of the package, and
a fifth terminal connected to the second electrode of the switching element and protruding from the second side of the package.

10. The power module according to claim 1, wherein
in each of the plurality of semiconductor groups, the second frame and the third frame have facing portions arranged in parallel with each other.

11. The power module according to claim 1, wherein
in each of the plurality of semiconductor groups, the first frame and the second frame have facing portions arranged in parallel with each other.

12. The power module according to claim 1, wherein
in two adjacent semiconductor groups among the plurality of semiconductor groups, the first frame of one semiconductor group and the second frame of the other semiconductor group have facing portions arranged in parallel with each other.

13. The power module according to claim 1, wherein
in one semiconductor group among the plurality of semiconductor groups, the third terminal protrudes from an end on any side of the package.

14. The power module according to claim 1, wherein
at least one semiconductor group among the plurality of semiconductor groups has no other terminal between the first terminal and the second terminal.

15. The power module according to claim 1, wherein
at least one semiconductor group among the plurality of semiconductor groups is controlled by hard switching, and at least another semiconductor group is controlled by soft switching.

16. The power module according to claim 15, wherein
in at least one semiconductor group of the at least one semiconductor group controlled by hard switching, at least one of the first semiconductor chip and the second semiconductor chip is a diode.

17. The power module according to claim 15, wherein
in the at least one semiconductor group controlled by soft switching, the first semiconductor chip and the second semiconductor chip are the same switching element.

18. The power module according to claim 15, wherein
the at least one semiconductor group controlled by hard switching constitutes a PFC circuit, and
the at least one semiconductor group controlled by soft switching constitutes a DC/DC converter.

19. The power module according to claim 15, wherein
a carrier frequency of the at least one semiconductor group controlled by hard switching is lower than a carrier frequency of the at least one semiconductor group controlled by soft switching.

20. The power module according to claim 1, further comprising
a control circuit provided in the package that controls the first semiconductor chip and the second semiconductor chip.

21. A power conversion apparatus comprising:
a main conversion circuit that includes the power module according to claim 1 and converts and outputs input power; and
a control circuit that outputs a control signal for controlling the main conversion circuit to the main conversion circuit.
